(19) United States
(12) Patent Application Publication
(10) Pub. No.: US 2024/0274487 A1
(43) Pub. Date: Aug. 15, 2024

(54) ELECTRONIC DEVICE

(71) Applicant: InnoLux Corporation, Miao-Li County (TW)

(72) Inventor: Shu-Han YU, Miao-Li County (TW)

(21) Appl. No.: 18/411,729

(22) Filed: Jan. 12, 2024

(30) Foreign Application Priority Data
Feb. 14, 2023 (CN) 202310111934.1

(51) Int. Cl. H01L 23/31; H01L 23/00; H01L 25/16; H01L 27/12

(52) U.S. Cl. CPC H01L 23/3192; H01L 24/05; H01L 24/32; H01L 25/167; H01L 27/124; H01L 2224/05571; H01L 2224/32225

(57) ABSTRACT

An electronic device includes: a first substrate, a function layer, a wire structure, a second substrate, an adhesive layer and a shading layer. The first substrate has a first surface, a second surface and a side surface. The function layer is disposed on the first surface. The wire structure is disposed on the first substrate, and is electrically connected with the function layer and includes a side wire disposed on the side surface of the first surface and a first wire disposed on the second surface. The second substrate is opposite to the first substrate. The adhesive layer is disposed between the first substrate and the second substrate. The shading layer is disposed on a side surface of the adhesive layer, and covers the side wire.

### CROSS-REFERENCE TO RELATED APPLICATIONS

This application claims the benefits of the Chinese Patent Application Serial Number 202310111934.1, filed on Feb. 14, 2023, the subject matter of which is incorporated herein by reference.

### BACKGROUND

### Field of the Disclosure

The present disclosure relates to an electronic device and, more particularly, to an electronic device capable of forming a tiled device.

### Description of Related Art

Multiple electronic devices, such as multiple display devices, may be used to implement a seamless tiled application. In seamless tiled application, the metal wires of the display device are typically arranged on the side or back of its substrate. However, the manufacturing process of the display device may cause damage to the metal wires and affect the panel yield. Moreover, the tiled gap between display devices may also cause light leakage. In addition, the metal wires disposed on the side or back of the substrate are usually exposed, which may fail to meet the environmental reliability requirements.

Therefore, there is a need for an electronic device to mitigate and/or obviate the aforementioned problems.

### SUMMARY

The present disclosure provides an electronic device. The electronic device includes a first substrate, a function layer, a wire structure, a second substrate, an adhesive layer and a shading layer. The first substrate has a first surface, a second surface and a side surface, wherein the first surface is opposite to the second surface, and the side surface is disposed between the first surface and the second surface. The function layer is disposed on the first surface. The wire structure is disposed on the first substrate and electrically connected to the function layer, and includes a side wire disposed on the side surface of the first substrate and a first wire disposed on the second surface. The second substrate is disposed opposite to the first substrate. The adhesive layer is disposed between the first substrate and the second substrate. The shading layer is disposed on a side surface of the adhesive layer and covers the side wire.

Other novel features of the disclosure will become more apparent from the following detailed description when taken in conjunction with the accompanying drawings.

### BRIEF DESCRIPTION OF DRAWINGS

FIG. 1A is a schematic diagram of a tiled device formed by electronic devices according to an embodiment of the present disclosure;

FIG. 1B is a schematic cross-sectional view of the tiled device corresponding to the section line in FIG. 1A;

FIG. 2 is a schematic diagram of an electronic device according to an embodiment of the present disclosure;

FIG. 3 is a schematic diagram of an electronic device according to another embodiment of the present disclosure;

FIG. 4 is a schematic diagram of a function layer of an electronic device according to an embodiment of the present disclosure;

FIG. 5 is a schematic diagram of an electronic device according to another embodiment of the present disclosure;

FIG. 6 is a schematic diagram of an electronic device according to another embodiment of the present disclosure;

FIG. 7 is a schematic diagram of an electronic device according to another embodiment of the present disclosure;

FIG. 8 is a schematic diagram of an electronic device according to another embodiment of the present disclosure;

FIG. 9 is a schematic diagram of an electronic device according to another embodiment of the present disclosure; and

FIG. 10 is a schematic diagram of an electronic device according to another embodiment of the present disclosure.

### DETAILED DESCRIPTION OF EMBODIMENT

Reference will now be made in detail to exemplary embodiments of the present disclosure, examples of which are illustrated in the accompanying drawings. Wherever possible, the same reference numerals are used in the drawings and description to refer to the same or like parts.

Throughout the specification and the appended claims, certain terms may be used to refer to specific components. Those skilled in the art will understand that electronic device manufacturers may refer to the same components by different names. The present disclosure does not intend to distinguish between components that have the same function but have different names. In the following description and claims, words such as “containing” and “comprising” are open-ended words, and should be interpreted as meaning “including but not limited to”.

Directional terms mentioned in the specification, such as “up”, “down”, “front”, “rear”, “left”, “right”, etc., only refer to the directions of the drawings. Accordingly, the directional term used is illustrative, not limiting, of the present disclosure. In the drawings, various figures illustrate the general characteristics of methods, structures and/or materials used in particular embodiments. However, these drawings should not be construed to define or limit the scope or nature encompassed by these embodiments. For example, the relative sizes, thicknesses and positions of various layers, regions and/or structures may be reduced or enlarged for clarity.

One structure (or layer, component, substrate) described in the present disclosure is disposed on/above another structure (or layer, component, substrate), which can mean that the two structures are adjacent and directly connected, or can refer to two structures that are adjacent rather than directly connected. Indirect connection means that there is at least one intermediate structure (or intermediate layer, intermediate component, intermediate substrate, intermediate space) between the two structures, the lower surface of one structure is adjacent to or directly connected to the upper surface of the intermediate structure, and the upper surface of the other structure is adjacent to or directly connected to the lower surface of the intermediate structure. The intermediate structure may be a single-layer or multi-layer physical structure or a non-physical structure, which is not limited. In the present disclosure, when a certain structure is arranged “on” other structures, it may mean that a certain structure is “directly” on other structures, or it means that a certain structure is “indirectly” on other structures; that is, at least one structure is sandwiched, in between a certain structure and other structures.

The terms, such as “about”, “equal to”, “equal” or “same”, “substantially”, or “substantially”, are generally interpreted as within 20% of a given value or range, or as within 10%, 5%, 3%, 2%, 1%, or 0.5% of a given value or range.

Furthermore, any two values or directions used for comparison may have certain errors. If the first value is equal to the second value, it implies that there may be an error of about 10% between the first value and the second value. If the first direction is perpendicular or “approximately” perpendicular to the second direction, the angle between the first direction and the second direction may be between 80 degrees and 100 degrees. If the first direction is parallel or “substantially” parallel to the second direction, the angle between the first direction and the second direction may be between 0 degrees and 10 degrees. In addition, for the convenience of description, the term “in a direction” hereinafter may refer to “approximately in this direction” or “approximately in a direction opposite to this direction”, while it is not limited thereto.

In the specification and claims, unless otherwise specified, ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method. Thus, what is referred to as a “first component” in the specification may be referred to as a “second component” in the claims.

In the present disclosure, the terms “the given range is from the first numerical value to the second numerical value” and “the given range falls within the range from the first numerical value to the second numerical value” mean that the given range includes the first numerical value, the second value, and other values therebetween.

In addition, the method disclosed in the present disclosure may be used in electronic devices, and electronic devices may include imaging devices, assembled devices, display devices, backlight devices, antenna devices, sensing devices, tiled devices, touch displays, curved displays or free shape displays, but it is not limited thereto. When the electronic device is an assembled device or a tiled device, the electronic device may include a grabbing mechanism, but it is not limited thereto. The electronic device may include, for example, liquid crystal, light emitting diode, fluorescence, phosphor, other suitable display media, or a combination thereof, but it is not limited thereto. The display device may be a non-self-luminous display device or a self-luminous display device. The antenna device may include, for example, a frequency selective surface (FSS), a radio frequency filter (RF-filter), a polarizer, a resonator, an antenna, etc. The antenna device may be a liquid crystal type antenna device or a non-liquid crystal type antenna device, and the sensing device may be a sensing device for sensing capacitance, light, thermal energy or ultrasonic waves, but it is not limited thereto. The tiled device may be, for example, a display tiled device or an antenna tiled device, but it is not limited thereto. In the present disclosure, the electronic device may include electronic components, and the electronic components may include passive components and active components, such as capacitors, resistors, inductors, diodes, transistors, and the like. The diodes may include light emitting diodes or photodiodes. The light emitting diodes may, for example, include organic light emitting diodes (OLEDs), sub-millimeter light emitting diodes (mini LEDs), micro light emitting diodes (micro LEDs) or quantum dot light emitting diodes (quantum dot LEDs), but it is not limited to. It should be noted that the electronic device may be any permutation and combination of the aforementioned, but it is not limited thereto. In addition, the electronic device may be a bendable or flexible electronic device. It should be noted that the electronic device may be any permutation and combination of the aforementioned, but it is not limited thereto. In addition, the shape of the electronic device may be rectangular, circular, polygonal, with curved edges, or other suitable shapes. The electronic device may have peripheral systems such as a driving system, a control system, a light source system, a shelf system, etc. to support a display device, an antenna device or a tiled device.

It is noted that the following are exemplary embodiments of the present disclosure, but the present disclosure is not limited thereto, while a feature of some embodiments can be applied to other embodiments through suitable modification, substitution, combination, or separation. In addition, the present disclosure can be combined with other known structures to form further embodiments.

Unless otherwise defined, all terms (including technical and scientific terms) used herein have the same meaning as commonly understood by those skilled in the art related to the present disclosure. It can be understood that these terms, such as those defined in commonly used dictionaries, should be interpreted as having meaning consistent with the relevant technology and the background or context of the present disclosure, and should not be interpreted in an idealized or excessively formal way. Unless there is a special definition in the embodiment of the present disclosure.

In addition, the term “adjacent” in the specification and claims is used to describe mutual proximity, and does not necessarily mean mutual contact.

In addition, descriptions such as “when” or “while” in the present disclosure represent aspects such as “now, before or after”, and are not limited to situations that occur at the same time. In the present disclosure, similar descriptions such as “disposed on” refer to the corresponding positional relationship between the two components, and do not limit whether there is contact between the two components, unless otherwise specified. Furthermore, when the present disclosure provides multiple functions, if the word “or” is used between the functions, it means that the functions may exist independently, but it does not exclude that multiple functions may exist simultaneously.

In addition, words such as “connect” or “couple” in the specification and claims not only refer to direct connection with another component, but also refer to indirect connection or electrical connection with another component. In addition, the electrical connection includes direct connection, indirect connection or radio signal communication between two components.

For the convenience of description, the electronic device will be described below as a display device, but the disclosure is not limited thereto.

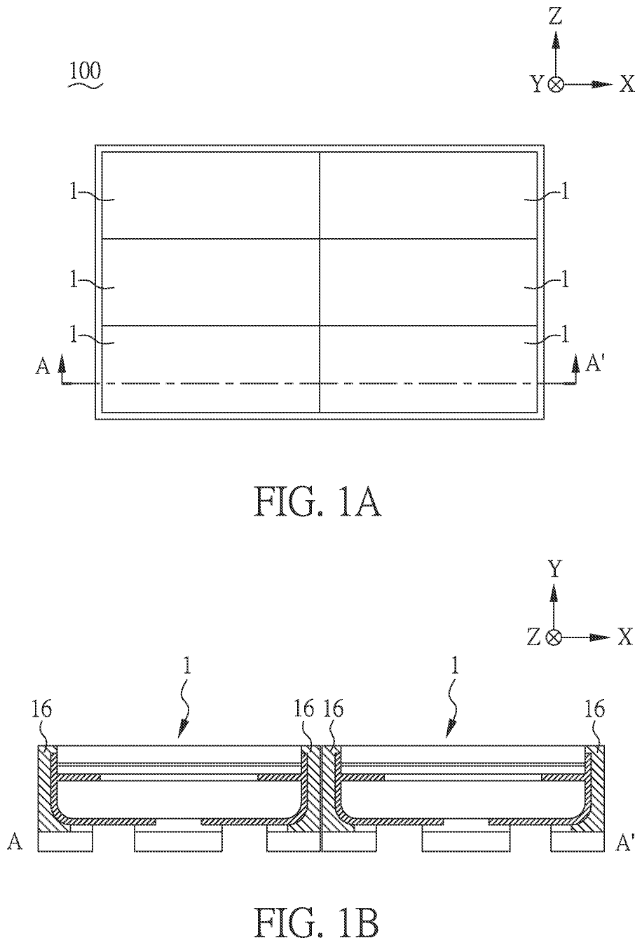

FIG. 1A is a schematic diagram of a tiled device 100 formed by a plurality of electronic devices 1 according to an embodiment of the present disclosure. As shown in

FIG. 1A, the tiled device 100 is formed by tiling a plurality of electronic devices 1 together.

In one embodiment, the electronic device 1 may be, for example, a micro light emitting diode display (micro-LED display) or other types of display devices, but it is not limited thereto. In order to implement the tiled device 100, the electronic device 1 may be provided with metal wires (such as the wire structure 13 in FIG. 3) by way of side wiring and/or backside wiring.

FIG. 1B is a schematic diagram of the tiled device 100 corresponding to the AA′ section line in FIG. 1A, which shows the cross-sectional view of the tiled device 100 formed by the section line AA′, and takes two tiled electronic devices 1 as an example. As shown in FIG. 1B , at least one shading layer 16 is disposed around the electronic device 1, which may reduce side light leakage of the electronic device 1, and thus improve the visual quality of the tiled device 100.

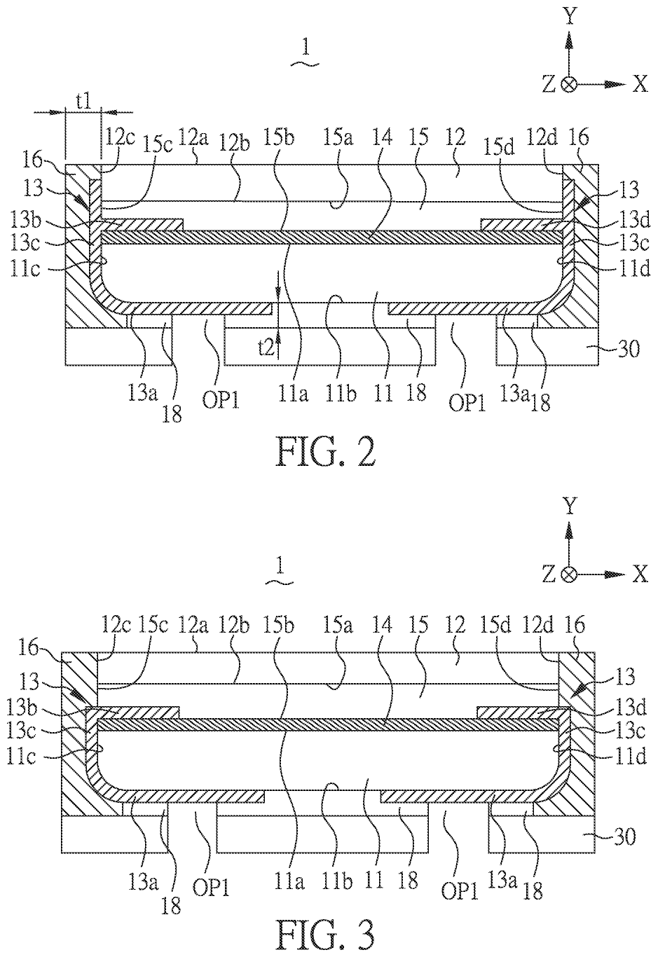

FIG. 2 is a schematic diagram of an electronic device 1 according to an embodiment of the present disclosure, which takes one electronic device 1 in FIG. 1B as an example, and please refer to FIG. 1A and FIG. 1B at the same time.

As shown in FIG. 2, the electronic device 1 includes a first substrate 11, a second substrate 12, at least one wire structure 13, a function layer 14, an adhesive layer 15 and at least one shading layer 16. In addition, the electronic device 1 may further include a protection layer 18 and a reinforcing plate 30.

First, the first substrate 11 will be described. The first substrate 11 has a first surface 11a, a second surface 11b, one side surface (hereinafter referred to as a third surface 11c) and another side surface (hereinafter referred to as a fourth surface 11d), wherein the first surface 11a and the second surface 11b extend in a first direction (X direction, such as the tangential direction of the first surface 11a), and the third surface 11c and the fourth surface 11d extend in a second direction (Y direction, such as the tangential direction of the third surface 11c). The first surface 11a is opposite to the second surface 11b, the third surface 11c is opposite to the fourth surface 11d, and the third surface 11c and the fourth surface 11d are each disposed between the first surface 11a and the second surface 11b. The material of the first substrate 11 may be, for example, glass or plastic, but it is not limited thereto. In one embodiment, thin film transistors (TFTs) may be disposed on the first substrate 11; for example, in the second direction (Y), a function layer 14 is disposed on the first substrate 11, and the function layer 14 includes thin film transistors, but it is not limited thereto.

Next, the second substrate 12 will be described. The second substrate 12 is disposed opposite to the first substrate 11. The second substrate 12 has a fifth surface 12a, a sixth surface 12b, one side surface (hereinafter referred to as a seventh surface 12c) and another side surface (hereinafter referred to as an eighth surface 12d), wherein the fifth surface 12a and the sixth surface 12b extend in the first direction (X), and the seventh surface 12c and the eighth surface 12d extend in the second direction (Y). The fifth surface 12a is opposite to the sixth surface 12b, and the seventh surface 12c is opposite to the eighth surface 12d. In addition, the seventh surface 12c and the eighth surface 12d are each disposed between the fifth surface 12a and the sixth surface 12b. In addition, the sixth surface 12b may be adjacent to the first surface 11a when observing from a cross-sectional view direction (e.g., Z direction). The material of the second substrate 12 may be, for example, glass or plastic, but it is not limited thereto. In one embodiment, a color filter (CF), a quantum dot (QD) film, and a black matrix (BM) material may be disposed on the second substrate 12, while it is not limited thereto. In another embodiment, the second substrate 12 may be a transparent resin or a polarizer, but it is not limited thereto. In the embodiment of FIG. 2, in the second direction (Y), a color filter (not shown) may be disposed on the second substrate 12.

Next, the wire structure 13 will be described. When observing from the cross-sectional view direction, the electronic device 1 may include two wire structures 13 symmetrically disposed on two sides of the electronic device 1 in the first direction (X), but it is not limited thereto. Since the two wire structures 13 are the same in configuration, only one of the wire structures 13 will be used for illustration below.

The wire structure 13 is disposed on the first substrate 11, and is electrically connected to the function layer 14. The wire structure 13 may include a first wire 13a, a second wire 13b and a side wire 13c electrically connected to each other. When observing from the cross-sectional view direction, the first wire 13a is disposed on the second surface 11b of the first substrate 11, and the second wire 13b is disposed on the first surface 11a of the first substrate 11. In the first direction (X), the side wire 13c is disposed on the third surface 11c of the first substrate 11. The wire structure 13 may be electrically connected with various electrical components to realize, for example, the electrical connection among the first substrate 11, the function layer 14, an integrated circuit (not shown) and/or other electrical components. In the embodiment of FIG. 2, the side wire 13c of the wire structure 13 extends in the second direction (Y), and is in contact with the function layer 14 and the second substrate 12, but it is not limited thereto. In one embodiment, the material of the wire structure 13 may include metal, while it is not limited thereto. The wire structure 13 may be used to implement metal wires for side wiring and/or back wiring.

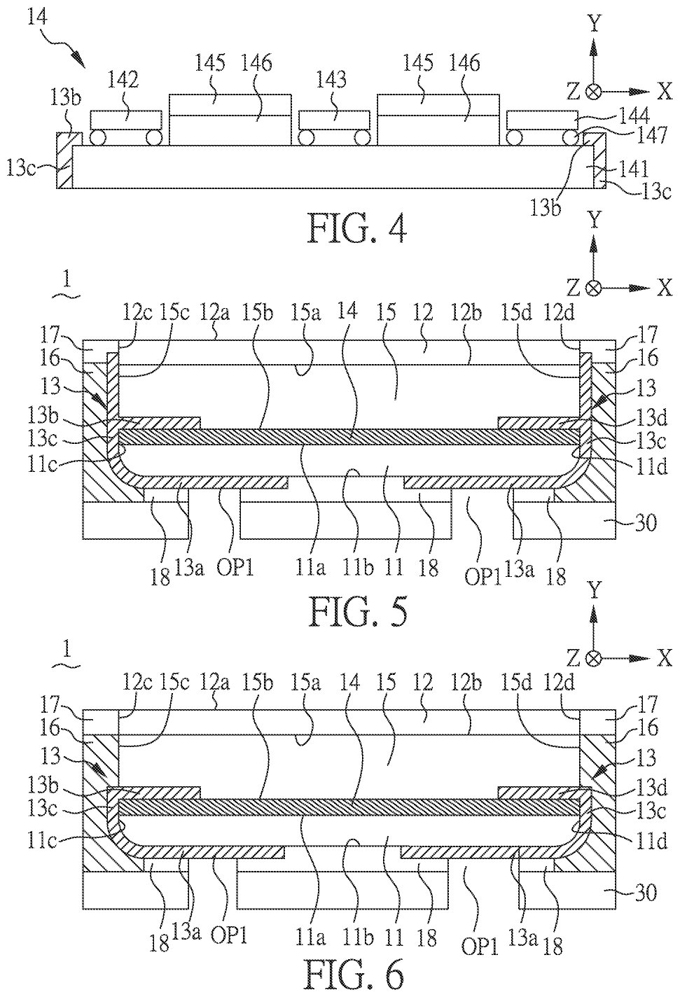

Next, the function layer 14 will be described. The function layer 14 may be disposed on the first surface 11a of the first substrate 11. More details of the function layer 14 will be described in subsequent paragraphs (with reference to the description of FIG. 4).

Next, the adhesive layer 15 will be described. The adhesive layer 15 may be disposed between the first substrate 11 and the second substrate 12. The adhesive layer 15 may include a ninth surface 15a, a tenth surface 15b, an eleventh surface 15c and a twelfth surface 15d, wherein the ninth surface 15a and the tenth surface 15b extend in the first direction (X), the eleventh surface 15c and the twelfth surface 15d extend in the second direction (Y), the ninth surface 15a is opposite to the tenth surface 15b, the eleventh surface 15c is opposite to the twelfth surface 15d, and the eleventh surface 15c and the twelfth surface 15d are each disposed between the ninth surface 15a and the tenth surface 15b. In one embodiment, the material of the adhesive layer 15 may include optical clear adhesive (OCA), liquid optical clear adhesive (LOCA) or other materials with similar functions, but it is not limited thereto.

Next, the shading layer 16 will be described. When observing from the cross-sectional view direction, the electronic device 1 may include two shading layers 16 symmetrically arranged on both sides of the electronic device 1 in the first direction (X), but it is not limited thereto. Since the two shading layers 16 have the same structure, only one of the shading layers 16 is used for illustration in the following.

In the first direction (X), the shading layer 16 may be disposed on the side surface of the adhesive layer 15 (e.g., the eleventh surface 15c), and covers the side wire 13. In one embodiment, the shading layer 16 may extend in the second direction (Y), and then is disposed on the side surface of the first substrate 11 (e.g., the third surface 11c). In one embodiment, the shading layer 16 may extend to the second substrate 12 in the second direction (Y), thereby covering the seventh surface 12c of the second substrate 12, but it is not limited thereto. In one embodiment, the shading layer 16 may extend to the first substrate 11 in the second direction (Y), thereby covering part of the side wire 13c disposed on the third surface 11c of the first substrate 11, but it is not limited thereto. In addition, in some embodiments, part of the shading layer 16 may extend in the first direction (X) and is in contact with the seventh surface 12c of the second substrate 12, while another part of the shading layer 16 may extend in the first direction (X) and is in contact with the protection layer 18, whereby the shading layer 16 and the protection layer 18 may cover the side wire 13c of the wire structure 13 and at least part of the first wire 13a. In one embodiment, the shading layer 16 may be, for example, a black sealant, which may reduce side light leakage of the electronic device 1, but it is not limited thereto. In one embodiment, the material of the shading layer 16 may include acrylic, polyurethane (PU), epoxy, etc., but it is not limited thereto.

In one embodiment, the shading layer 16 has a first thickness t1 in the first direction (X), which is defined as the thickness of the shading layer 16 in the first direction (X). For example, it may be the maximum thickness of the shading layer 16 in the first direction (X). In one embodiment, the first thickness t1 may be between 1 micrometer (μm) and 100 micrometers (i.e., 1 μm≤t1≤1100 μm), while it is not limited thereto. In one embodiment, the first thickness t1 may be between 1 micrometer (μm) and 30 micrometers (i.e., 1 μm≤t1≤30 μm), while it is not limited thereto. With the aforementioned design, when multiple electronic devices 1 are used to form a tiled device, the shading layer 16 will not affect the visual effect of tiling, for example, the tiled part of the tiled device is hard to be observed.

In one embodiment, the optical density (OD) of the shading layer 16 may be greater than or equal to 3 (i.e., OD≥3), while it is not limited thereto. As a result, the problem of side light leakage of the electronic device 1 can be reduced.

In one embodiment, the pencil hardness (H) of the shading layer 16 may be greater than 8 hardness (that is, pencil hardness>8 H), while it is not limited thereto. As a result, the scratch resistance of the shading layer 16 may be improved, so as to prevent the wire structure 13 from being scratched and affecting the operation of the electronic device 1.

In one embodiment, the water vapor transmission rate (WVTR) of the shading layer 16 may be smaller than 50 grams/square meter/day (g/m² /day) (that is, WVTR<50g/m²/day), but it is not limited to. In one embodiment, the water vapor transmission rate of the shading layer 16 may be smaller than 1 g/m²/day (that is, WVTR<1 g/m²/day), while it is not limited thereto. In one embodiment, the water vapor transmission rate of the shading layer 16 may be smaller than 0.01 g/m²/day (that is, WVTR<0.01 g/m²/day), while it is not limited thereto. As a result, the water vapor blocking capability of the electronic device 1 can be improved, thereby increasing the reliability of the electronic device 1.

The parameters of the shading layer 16 may be adjusted and designed according to the requirements. For example, when water vapor blocking capability and scratch resistance are required, the water vapor transmission rate and the pencil hardness of the shading layer 16 must meet the values of the aforementioned embodiments, and so on.

Next, the protection layer 18 will be described. The protection layer 18 may be disposed on the second surface 11b of the first substrate 11, and at least part of the protection layer 18 covers the first wire 13a. In one embodiment, the protection layer 18 may be transparent glue, and the material of the transparent glue may include acrylic, polyurethane (PU), epoxy, etc., but it is not limited thereto. In one embodiment, the protection layer 18 has a patterned design; that is, it may have an opening OP1 to facilitate subsequent IC bonding.

In one embodiment, the protection layer 18 has a second thickness t2 in the second direction (Y), which is defined as the thickness of the protection layer 18 in the second direction (Y). For example, it may be the maximum thickness of the protection layer 18 in the second direction (Y). In one embodiment, the second thickness t2 may be between 1 micrometer and 100 micrometers (that is, 1 μ≤t2≤100 μm), but it is not limited thereto. In one embodiment, the second thickness t2 may be between 1 micrometer (μm) and 30 micrometers (that is, 1 μm≤t2≤30 μm), while it is not limited thereto. In one embodiment, the second thickness t2 is designed to cover the first wire 13a of the wire structure 13 to effectively protect the wire structure 13.

In one embodiment, the pencil hardness of the protection layer 18 may be greater than 8 hardness (that is, pencil hardness>8 H), while it is not limited thereto. As a result, the scratch resistance of the protection layer 18 may be improved, so as to prevent the wire structure 13 from being scratched and affecting the operation of the electronic device 1.

In one embodiment, the water vapor transmission rate of the protection layer 18 may be smaller than 50 g/m²/day (that is, WVTR<50 g/m²/day), while it is not limited thereto. In one embodiment, the water vapor transmission rate of the protection layer 18 may be smaller than 1 g/m²/day (that is, WVTR<1 g/m²/day), but it is not limited thereto. In one embodiment, the water vapor transmission rate of the protection layer 18 may be smaller than 0.01 g/m²/day (that is, WVTR<0.01 g/m²/day), but it is not limited thereto. As a result, the water vapor blocking capability of the electronic device 1 can be improved, thereby increasing the reliability of the electronic device 1.

The parameters of the protection layer 18 may be adjusted and designed according to the requirements. For example, when water vapor blocking capability and the scratch resistance are required, the water vapor transmission rate and the pencil hardness of the protection layer 18 must meet the values of the aforementioned embodiments, and so on.

In one embodiment, when observing from the cross-sectional view direction (Z), a reinforcing plate 30 is arranged on the bottom of the protection layer 18 in the second direction (Y) (for example, the side away from the second surface 11b), so as to reinforce the stability of the overall structure of the electronic device 1, but it is not limited thereto. The materials of the protection layer 18 and the reinforcing plate 30 may be various suitable plastic materials, such as plastic, acrylic silicon and so on, but it is not limited thereto.

In one embodiment, the junction of different surfaces of the first substrate 11 of the electronic device 1 (such as the junction of the second surface 11b and the third surface 11c, and/or the junction of the second surface 11b and the fourth surface 11d) may be designed as an arc shape or a chamfer shape. Therefore, the components disposed on the first substrate 11 may present an arc or chamfer at the junction of at least any two extending directions (for example, the junction of the side wire 13c and the first wire 13a of the wire structure 13, or the junction of the side wire 13c and the second wire 13b), so that the wires extending in different directions may be effectively electrically connected, but it is not limited thereto. In some embodiments, it may also be designed as a right angle according to the requirements.

As a result, the wire structure 13 may be covered by the shading layer 16 and the protection layer 18, thereby reducing the damage of the wire structure 13. Alternatively, with the arrangement of the shading layer 16, it is able to reduce the problem of light leakage through the gaps of the tiled device 100 formed by multiple electronic devices 1. Therefore, the present disclosure is able to mitigate and/or obviate the problems of the prior art.

The second substrate 12 of the present disclosure may have different implementations. FIG. 3 is a schematic diagram of an electronic device 1 according to another embodiment of the present disclosure, and please refer to FIG. 1A to FIG. 2 at the same time. Most of the features of the embodiment in FIG. 3 are applicable to the description of the embodiment in FIG. 2, and thus the following description will mainly focus on the differences.

Different from the embodiment in FIG. 2, the second substrate 12 in the embodiment in FIG. 3 may be a transparent resin or a polarizer. As shown in FIG. 3, the side wires 13 of the wire structure 13 extend to the function layer 14 or the adhesive layer 15 in the second direction (Y).

Next, an arrangement of the function layer 14 will be described. FIG. 4 is a schematic diagram of the function layer 14 according to an embodiment of the present disclosure, which shows the structure of the function layer 14 from the viewpoints of FIG. 2 and FIG. 3, and please refer to FIG. 1A to FIG. 3 at the same time.

As shown in FIG. 4, the function layer 14 may at least include a circuit layer 141, a first electronic unit 142, an electronic unit 143 and a third electronic unit 144. The circuit layer 141 may include transistors, signal lines, and metal lines, but it is not limited thereto. The second wire 13b of the wire structure is disposed on the circuit layer and is electrically connected to the circuit layer 141. The first electronic unit 142, the second electronic unit 143, and the third electronic unit 144 may be disposed on the circuit layer 141 and electrically connected to the circuit layer 141, but it is not limited thereto. In some embodiments, the first electronic unit 142, the second electronic unit 143 and the third electronic unit 144 may be electrically connected to the circuit layer 141 through corresponding connection pads 147, but it is not limited thereto. In some embodiments, the function layer 14 may further include a pixel define layer (PDL) 146, and the pixel define layer 146 may be disposed on the circuit layer 141 and between any two electronic units, but it is not limited thereto. In other embodiments, the function layer 14 may include a black matrix material 145 and a pixel define layer (PDL) 146, and the black matrix material 145 may be disposed on the circuit layer 141 or further disposed on the pixel define layer 146. When the electronic device is a display device, the electronic unit may be, for example, a light emitting diode unit. Therefore, the first electronic unit 142, the second electronic unit 143 and the third electronic unit 144 may respectively emit light of different colors, such as red light, blue light and green light, but it is not limited thereto. In other embodiments, the first electronic unit 142, the second electronic unit 143 and the third electronic unit 144 may emit light of the same color, such as blue light.

The function layer 14 and the second substrate 12 (with reference to the embodiment in FIG. 2 or the embodiment in FIG. 3) may have different configurations. In one embodiment, the black matrix material 145 may be disposed on the second substrate 12 and, at this time, the function layer 14 may not have the black matrix material 145 while the function layer 14 may or may not have the pixel define layer 146. In another embodiment, when the black matrix material 145 is not provided on the second substrate 12 (for example, when the second substrate 12 is a transparent resin or a polarizer), the function layer 14 may be provided with a black matrix material 145, and the function layer 14 may or may not be provided with the pixel define layer 146, while the present disclosure is not limited thereto. As a result, the configuration of the function layer 14 can be understood.

Next, different implementation aspects of the electronic device 1 will be described. FIG. 5 is a schematic diagram of an electronic device 1 according to another embodiment of the present disclosure, which is presented from the viewpoint of FIG. 2, and please refer to FIG. 1A to FIG. 4 at the same time. Most of the features of the embodiment in FIG. 5 are applicable to the description of the embodiment in FIG. 2, and thus the following description will mainly focus on the differences.

As shown in FIG. 5, in order to achieve specific optical requirements, such as increasing the light output rate, the electronic device 1 may include two optical materials 17, which are symmetrically arranged on both sides of the electronic device 1 in the first direction (X), but it is not limited thereto. In the following, one of the optical materials 17 is taken as an example for illustration. When observing from the cross-sectional view direction, in the second direction (Y), the optical material 17 may be disposed on the shading layer 16. In addition, in the first direction (X), the optical material 17 may be disposed on the seventh surface 12c of the second substrate 12, that is, in the first direction (X), the optical material may be disposed adjacent to the second substrate 12, while it is not limited thereto. In addition, the second substrate 12 of the embodiment in FIG. 5 is a conductive substrate (such as the second substrate 12 of the embodiment in FIG. 2), so that the side wire 13c of the wire structure 13 extends to be in contact with the second substrate 12 in the second direction (Y).

In one embodiment, the absolute value of the difference between the refractive index of the optical material 17 and the refractive index of the second substrate 16 is greater than or equal to 0 and smaller than or equal to 0.1 (that is, 0≤|difference of the refractive index|≤0.1), while it is not limited thereto. In one embodiment, the absolute value of the difference between the refractive index of the optical material 17 and the refractive index of the second substrate 16 is greater than or equal to 0 and smaller than or equal to 0.05 (that is, 0≤|difference of refractive index|≤0.05), while it is not limited thereto. In one embodiment, the absolute value of the difference between the refractive index of the optical material 17 and the refractive index of the second substrate 16 is greater than or equal to 0 and smaller than or equal to 0.03 (that is, 0≤|difference in refractive index|≤0.03), while it is not limited thereto.

In one embodiment, the material of the optical material 17 may include optical glue, acrylic silicon, and so on, while it is not limited thereto.

In one embodiment, the optical material 17 may be integrally formed with the shading layer 16, for example, the shading layer 16 itself satisfies the refractive index condition of the aforementioned optical material 17, but it is not limited thereto, while the two may also be different components.

FIG. 6 is a schematic diagram of an electronic device 1 according to another embodiment of the present disclosure, which is presented from the viewpoint of the embodiment in FIG. 3, and please refer to FIG. 1A to FIG. 5 at the same time. Most of the features of the embodiment in FIG. 6 are applicable to the description of the embodiment in FIG. 3 or the embodiment in FIG. 5, and thus the following description will mainly focus on the differences.

As shown in FIG. 6, the electronic device 1 may include two optical materials 17 disposed symmetrically on both sides of the electronic device 1 in the first direction (X), but it is not limited thereto. In the following, one of the optical materials 17 is taken as an example for illustration. When observing from the cross-sectional view direction, in the second direction (Y), the optical material 17 may be disposed on the shading layer 16. In addition, in the first direction (X), the optical material 17 may be disposed on the seventh surface 12c of the second substrate 16, that is, in the first direction (X), the optical material may be disposed adjacent to the second substrate 12, while it is not limited thereto. In addition, the second substrate 12 in the embodiment of FIG. 6 may be a plastic substrate, and the side wire 13c of the wire structure 13 is not in contact with the second substrate 12.

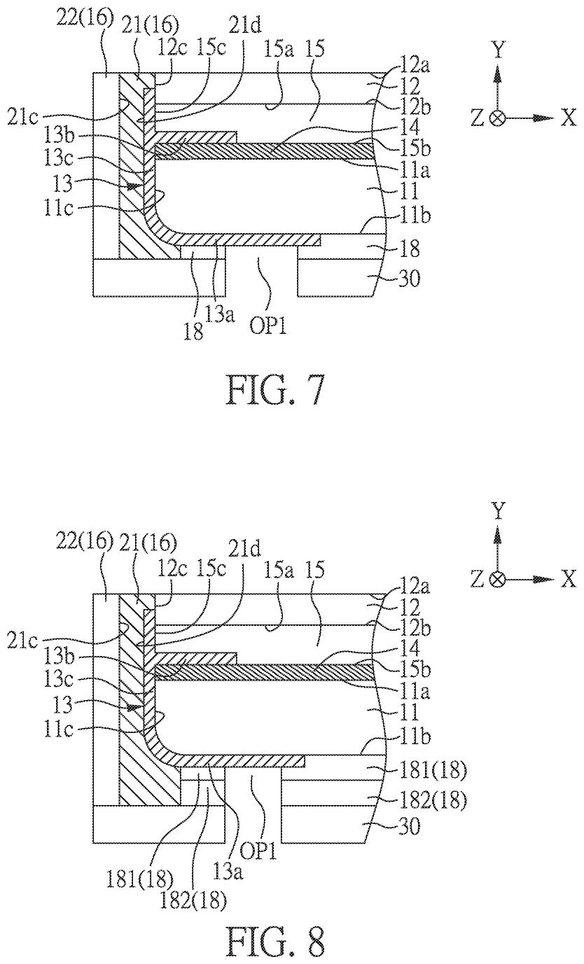

In addition, more shading layers may be provided on both sides of the electronic device 1 of the present disclosure. FIG. 7 is a schematic diagram of an electronic device 1 according to another embodiment of the present disclosure, which is presented from the viewpoint of FIG. 2 , and please refer to FIG. 1A to FIG. 6 at the same time. Since the electronic device 1 has a symmetrical structure in the first direction (X), FIG. 7 only shows part of the structure of the electronic device 1 for illustration, and those skilled in the art can deduce the structure of another part therefrom.

Most of the features of the embodiment in FIG. 7 are applicable to the description of the embodiment in FIG. 2, and thus the following description will mainly focus on the differences. As shown in FIG. 7, the shading layer 16 may be a multi-layer structure, for example, may include a first sub-layer 21 and a second sub-layer 22. In the first direction (X), the first sub-layer 21 is disposed between the wire structure 13 and the second sub-layer 22. For example, the first sub-layer 21 may have a first side surface 21c and a second side surface 21d, the second side surface 21d of the first sub-layer 21 is adjacent to the wire structure 13, and the first side surface 21c of the first sub-layer 21 is adjacent to the second sub-layer 22.

In one embodiment, the first sub-layer 21 or the second sub-layer 22 may be applicable to various implementation aspects of the shading layer 16 in the aforementioned embodiments, such as thickness, optical density, pencil hardness and/or water oxygen blocking capacity, etc., while it is not limited thereto. In one embodiment, the second sub-layer 22 may have different functions from the first sub-layer 21, for example, the first sub-layer 21 may have a shading function, while the second sub-layer 22 may have scratch resistance and water oxygen blocking capability. In this case, the optical density of the first sub-layer 21 may be subject to the numerical ranges defined in the aforementioned embodiments, and the pencil hardness and water oxygen blocking capability of the second sub-layer 22 may be subject to the numerical ranges defined in the aforementioned embodiments, and so on. In one embodiment, the sub-layer of the shading layer farthest from the wire structure 13 (for example, the second sub-layer 22 in FIG. 7) generally has the function of scratch resistance.

FIG. 8 is a schematic diagram of an electronic device 1 according to another embodiment of the present disclosure, which is presented from the viewpoint of FIG. 2, and please refer to FIG. 1A to FIG. 7 at the same time. Since the electronic device 1 has a symmetrical structure in the first direction (X), FIG. 8 only shows part of the structure of the electronic device 1 for illustration, and those skilled in the art can deduce the structure of another part therefrom.

Most of the features of the embodiment in FIG. 8 are applicable to the descriptions of the embodiments in FIG. 2 and FIG. 7, and thus the following will mainly focus on the differences. As shown in FIG. 8, the shading layer 16 may be a multi-layer structure, for example, may include a first sub-layer 21 and a second sub-layer 22. In the first direction (X), the first sub-layer 21 is disposed between the wire structure 13 and the second sub-layer 22, and the first sub-layer 21 and the second sub-layer 22 may be applicable to the description of the embodiment in FIG. 7. In addition, the protection layer 18 may be a multi-layer structure, for example, may include a first protection sub-layer 181 and a second protection sub-layer 182. In the second direction (Y), the first protection sub-layer 181 is disposed between the first substrate 11 and the second protection sub-layer 182.

In one embodiment, the first protection sub-layer 181 and the second protection sub-layer 182 may be applicable to various implementation aspects of the protection layer 18 in the aforementioned embodiments, such as thickness (t2, with reference to FIG. 2), pencil hardness and/or water oxygen blocking capability, etc., but it is not limited thereto. In one embodiment, the second protection sub-layer 182 and the first protection sub-layer 181 may have different functions, for example, the first protection sub-layer 181 may have the function of blocking water oxygen, while the second protection sub-layer 182 can have the function of resisting scratch. At this moment, the water oxygen blocking capability of the first protection sub-layer 181 may be subject to the numerical ranges defined in the aforementioned embodiments, and the pencil hardness of the second protection sub-layer 182 may be subject to the numerical ranges defined in the aforementioned embodiments, and so on. It should be noted that, in one embodiment, the outermost protection layer (that is, the sub-layer of the protection layer farthest from the first substrate 11 in the second direction (Y), such as the second protection sub-layer 182), usually has the function of scratch resistance, but it is not limited thereto.

The side or bottom of the electronic device 1 of the present disclosure may also have more sub-layers of the shading layer and/or sub-layers of the protection layer. FIG. 9 is a schematic diagram of an electronic device 1 according to another embodiment of the present disclosure, which is presented from the viewpoint of FIG. 2, and please refer to FIG. 1A to FIG. 8 at the same time. Since the electronic device 1 has a symmetrical structure in the first direction (X), FIG. 9 only shows part of the structure of the electronic device 1 for illustration, and those skilled in the art can deduce the structure of another part therefrom.

Most of the features of the embodiment in FIG. 9 are applicable to the description of the embodiments in FIG. 2 and FIG. 7, and thus the following description will mainly focus on the differences. As shown in FIG. 9, the shading layer 16 is a multi-layer structure, for example, may include a first sub-layer 21 , a second sub-layer 22 and a third sub-layer 23. In the first direction (X), the second sub-layer 22 is disposed between the first sub-layer 21 and the third sub-layer 23. For example, the second sub-layer 22 may have a third side surface 22c and a fourth side surface 22d, wherein the fourth side surface 22d of the second sub-layer 22 is adjacent to the first sub-layer 21, and the third side surface 22c of the second sub-layer 22 is adjacent to the third sub-layer 23.

In one embodiment, the first sub-layer 21, the second sub-layer 22 or the third sub-layer 23 may be applicable to various implementations of the shading layer 16 of the aforementioned embodiments, such as thickness (t1, with reference to FIG. 2), optical density, pencil hardness and/or water oxygen blocking capability, etc., while it is not limited thereto. In one embodiment, the third sub-layer 23 may have different functions from the second sub-layer 22 and/or the first sub-layer 21. For example, the first sub-layer 21 may have a shading function, and the second sub-layer 22 may have scratch resistance function, the third sub-layer 23 may have the functions of scratch resistance and water vapor blocking. At this moment, the optical density of the first sub-layer 21 may be subject to the numerical ranges defined in the aforementioned embodiments, the pencil hardness of the second sub-layer 22 may be subject to the numerical ranges defined in the aforementioned embodiments, the pencil hardness and the water oxygen blocking capability of the third sub-layer 23 may be subject to the numerical ranges defined in the aforementioned embodiments, and so on. It should be noted that, in one embodiment, the shading layer disposed on the outermost side (that is, the sub-layer of the shading layer farthest from the wire structure 13 in the first direction (X), for example, the third sub-layer 23) usually has scratch resistance function, but it is not limited thereto.

It should be noted that the number of sub-layers of the protection layer or the number of sub-layers of the shading layer in FIG. 7 to FIG. 9 is for illustrative purpose only, and may be adjusted according to actual needs. In addition, a conductive substrate is taken as an example for the second substrate 12 in FIG. 7 to FIG. 9, but it may also be replaced with a plastic substrate.

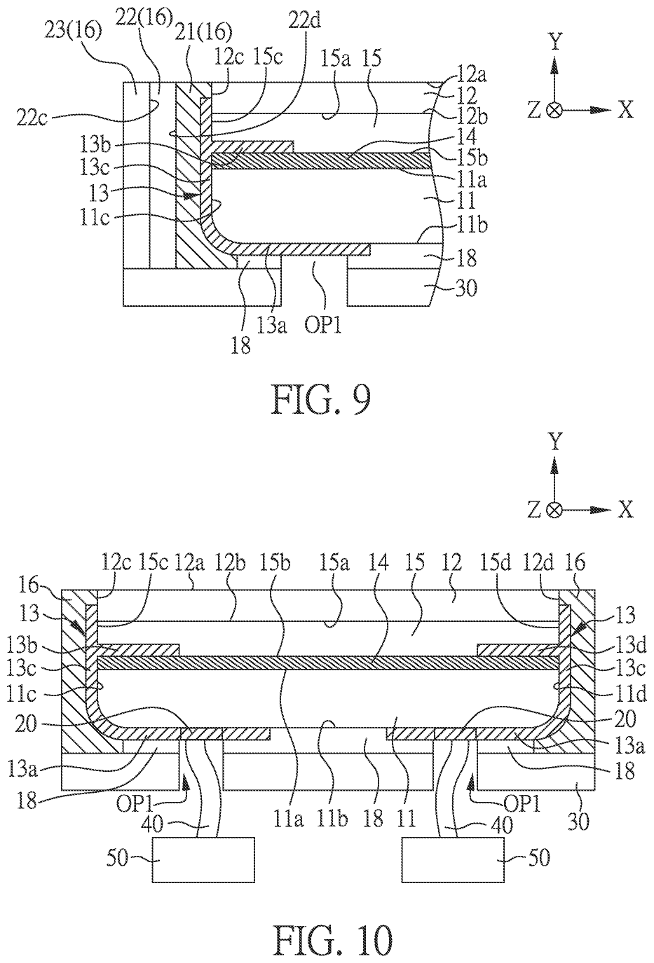

In addition, the electronic device 1 may also have different implementation aspects. FIG. 10 is a schematic diagram of an electronic device 1 according to another embodiment of the present disclosure, which is presented from the viewpoint of FIG. 2, and please refer to FIG. 1A to FIG. 9 at the same time. Most of the features of the embodiment in FIG. 10 are applicable to the description of the embodiment in FIG. 2, and thus the following description will mainly focus on the differences.

As shown in FIG. 10, an opening OP1 may be defined at corresponding positions of the protection layer 18 and the reinforcing plate 30 of the electronic device 1, and the first wire 13a further includes a bonding area 20. The position of the bonding area 20 may correspond to the opening OP1, that is, in the second direction (Y), the position of the bonding area 20 overlaps the position of the opening OP1, so the opening OP1 may expose the bonding area 20, while it is not limited thereto.

The bonding area 20 may include conductive material, such as metal or alloy, while it is not limited thereto. The bonding area 20 may be electrically connected to a conductive component 40, and electrically connected to a circuit board 50 through the conductive component 40. The circuit board 50 may be, for example, a printed circuit board (PCB) outside the electronic device 1, while it is not limited thereto. An integrated circuit (not shown) may be disposed on the circuit board 50, but it is not limited thereto.

Although a conductive substrate is taken as an example for the second substrate 12 in the embodiment of FIG. 10, in fact, a plastic substrate may also be used, while it is not limited thereto.

As a result, the electronic device 1 of the present disclosure can be understood.

In one embodiment, the present disclosure may at least compare the operation of an object by means of mechanism observation, for example, using the operation relationship between components as evidence of whether the operation of the object falls within the scope of protection of the present disclosure, while it is not limited thereto.

As a result, the present disclosure may protect the wire structure, or not affect the visual quality after tiling, thereby solving the problems of the prior art.

The details or features of the various embodiments disclosed in the present disclosure can be mixed and matched arbitrarily as long as they do not violate the spirit of the disclosure or conflict with each other.

The aforementioned specific embodiments should be construed as merely illustrative, and not limiting the rest of the present disclosure in any way.

1. An electronic device, comprising:
a first substrate having a first surface, a second surface and a side surface, wherein the first surface is opposite to the second surface, and the side surface is disposed between the first surface and the second surface;
a function layer disposed on the first surface;
a wire structure disposed on the first substrate and electrically connected to the function layer, and including a side wire disposed on the side surface of the first substrate and a first wire disposed on the second surface;
a second substrate disposed opposite to the first substrate;
an adhesive layer disposed between the first substrate and the second substrate; and
a shading layer disposed on a side surface of the adhesive layer and covers the side wire.

2. The electronic device as claimed in claim 1, wherein the shading layer is further disposed on the side surface of the first substrate.

3. The electronic device as claimed in claim 1, further comprising an optical material disposed on a side surface of the second substrate, wherein an absolute value of a difference between a refractive index of the optical material and a refractive index of the second substrate is greater than or equal to 0 and smaller than or equal to 0.1.

4. The electronic device as claimed in claim 1, wherein the optical density of the shading layer is greater than or equal to 3.

5. The electronic device as claimed in claim 1, wherein a thickness of the shading layer is between 1 micrometer and 100 micrometers.

6. The electronic device as claimed in claim 1, wherein a pencil hardness of the shading layer is greater than or equal to 8 hardness.

7. The electronic device as claimed in claim 1, wherein a water vapor transmission rate of the shading layer is smaller than or equal to 50 g/m²/day.

8. The electronic device as claimed in claim 1, further comprising a protection layer disposed on the second surface of the first substrate, wherein at least part of the protection layer covers the first wire.

9. The electronic device as claimed in claim 8, wherein the protection layer further comprises a first protection sub-layer and a second protection sub-layer, the first protection sub-layer is disposed between the first substrate and the second protection sub-layer.

10. The electronic device as claimed in claim 8, wherein the first wire further comprises a bonding area, and the protection layer is provided with an opening exposing the bonding area.

11. The electronic device as claimed in claim 1, wherein the shading layer comprises a first sub-layer and a second sub-layer, and the first sub-layer is disposed between the wire structure and the second sub-layer.

12. The electronic device as claimed in claim 11, wherein the shading layer further comprises a third sub-layer, and the second sub-layer is disposed between the first sub-layer and the third sub-layer.

13. The electronic device as claimed in claim 3, wherein the side wire extends to be in contact with the function layer and the second substrate.

14. The electronic device as claimed in claim 1, wherein the side wire extends to the function layer or the adhesive layer, and is not in contact with the second substrate.

15. The electronic device as claimed in claim 1, wherein the function layer at least includes a circuit layer, and a first electronic unit, a second electronic unit and a third electronic unit disposed on the circuit layer and electrically connected to the circuit layer.

16. The electronic device as claimed in claim 15, wherein the function layer further includes a pixel define layer disposed on the circuit layer and arranged between any two electronic units.

17. The electronic device as claimed in claim 8, wherein a thickness of the protection layer is between 1 micrometer and 100 micrometers.

18. The electronic device as claimed in claim 8, wherein a pencil hardness of the protection layer is greater than 8 hardness.

19. The electronic device as claimed in claim 8, wherein a water vapor transmission rate of the protection layer is smaller than 50 g/m²/day.

20. The electronic device as claimed in claim 8, further comprising a reinforcing plate disposed on a side of the protection layer away from the second surface.
